(19) United States
(12) Patent Application Publication
(10) Pub. No.: US 2009/0057855 A1
(43) Pub. Date: Mar. 5, 2009

(54) SEMICONDUCTOR DIE PACKAGE INCLUDING STAND OFF STRUCTURES

(76) Inventors: Maria Clemens Quinones, Cebu City (PH); Erwin Victor Cruz, Koronadal City (PH); Marvin Gestole, Cebu (PH); Ruben P. Madrid, Lapu-lapu City (PH); Connie N. Tangpuz, Lapu-lapu City (PH)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 11/847,670

(22) Filed: Aug. 30, 2007

(51) Int. Cl. H01L 23/495; H01L 21/00

(52) U.S. Cl. 257/676; 438/123; 257/E23.031

(57) ABSTRACT

A semiconductor die package. It includes a semiconductor die including a first surface and a second surface opposite the first surface, an optional conductive structure, and a leadframe structure. The leadframe structure comprises a central portion suitable for supporting the semiconductor die, and a plurality of stand-off structures coupled to the central portion of the leadframe structure. The stand-off structures can support the conductive structure, and the conductive structure is attached to the second surface of the semiconductor die.

### CROSS-REFERENCES TO RELATED APPLICATIONS

NOT APPLICABLE

### BACKGROUND

Semiconductor die packages are known in the semiconductor industry, but could be improved. For example, electronic devices such as wireless phones and the like are becoming smaller and smaller. It is desirable to make thinner semiconductor die packages, so that they can be incorporated into such electronic devices. It would also be desirable to improve upon the heat dissipation properties of conventional semiconductor die packages. Semiconductor die packages including power transistors, for example, generate a significant amount of heat.

It would also be desirable to provide for a semiconductor die package with planar surfaces. When the parts of a semiconductor die package are soldered together, the relative positions of the parts may shift, thereby resulting in package portions that are not planar. As a result, rework may be needed in some cases. In addition, when parts in a package are stacked together, parts in the package (e.g., the die and the solder) may experience stress, and could possibly crack. It would be desirable to provide for a package configuration that would provide less stress on certain parts within a package.

Embodiments of the invention address these and other problems, individually and collectively.

### BRIEF SUMMARY

Embodiments of the invention are directed to semiconductor die packages, clips, methods for making semiconductor die packages and clips, as well as electrical assemblies and systems.

One embodiment of the invention is directed to a leadframe structure. It includes a semiconductor die including a first surface and a second surface opposite the first surface, and a leadframe structure. The leadframe structure comprises a central portion comprising a planar surface suitable for supporting the semiconductor die, and a plurality of stand-off structures coupled to or spaced from the central portion of the leadframe structure.

Another embodiment of the invention is directed to a semiconductor die package comprising: a semiconductor die comprising a first surface and a second surface opposite the first surface; and a leadframe structure comprising a central portion comprising a planar surface suitable for supporting the semiconductor die, and a plurality of stand-off structures coupled to the central portion of the leadframe structure, wherein the stand-off structures are capable of maintaining planarity with respect to a conductive structure comprising a planar surface.

Another embodiment of the invention is directed to a method for forming a semiconductor die package, the method comprising: obtaining a semiconductor die comprising a first surface and a second surface opposite the first surface; obtaining a leadframe structure comprising a central portion comprising a planar surface suitable for supporting the semiconductor die, and a plurality of stand-off structures; and attaching the leadframe structure to the semiconductor die.

These and other embodiments of the invention are described in detail with in the Detailed Description with reference to the Figures. In the Figures, like numerals may reference like elements and descriptions of some elements may not be repeated.

### BRIEF DESCRIPTION OF THE DRAWINGS

FIGS. 1 and 2 respectively show a perspective top view and a perspective bottom view of a semiconductor die package.

FIGS. 3 and 4 respectively show cut-away perspective top and bottom views of a semiconductor die package.

FIG. 5 shows a longitudinal side view of a semiconductor die package.

FIG. 6. is a lateral cross-sectional view of the semiconductor die package.

FIG. 7 shows a perspective top view of a leadframe structure with stand off structures.

FIG. 8 shows a close up view of stand off features with a top set pad.

FIGS. 9(a)-9(c) show various stand off design options.

FIGS. 10(a)-10(c) show various cross-sectional views of packages with the stand off design options shown in FIGS. 9(a)-9(c).

FIG. 11(a) shows a package construction with an exposed top drain.

FIG. 11(b) shows the package in FIG. 11(a) with a portion of the molding material cut away.

FIG. 12 shows a bottom leadframe structure.

FIG. 13 shows a flowchart with steps that are common to both top and bottom exposed packages.

FIG. 14 shows another application of the non-electrical contact stand-off structures.

FIG. 15 shows a semiconductor die comprising a vertical MOSFET with a trenched gate.

FIG. 16 shows a top view of another semiconductor die package.

FIG. 17 shows a bottom view of the semiconductor die package in FIG. 16.

FIG. 18 shows a perspective view of the semiconductor die package in FIG. 16, with an outline of the molding material being shown.

FIG. 19 shows a perspective view of the semiconductor die package in FIG. 18, with an outline of the molding material being shown.

FIGS. 20(a)-20(i) show various structures that can be formed when forming a semiconductor die package.

FIG. 21 shows a side view of an electrical assembly including a semiconductor die package and a printed circuit substrate.

### DETAILED DESCRIPTION

One embodiment of the invention is directed to a semiconductor die including a first surface and a second surface opposite the first surface, a conductive structure, and a leadframe structure. The leadframe structure comprises a central portion suitable for supporting the semiconductor die, and a plurality of stand-off structures coupled to (e.g., extending from) the central portion of the leadframe structure. The stand-off structures support the conductive structure, and the conductive structure is attached to the second surface of the semiconductor die. The conductive structure may comprise a combination of insulating and conductive material, and may be a premolded clip, a circuit substrate, etc.

In some embodiments, multiple components can be inside of a semiconductor die package. Bottom and top functional pads can be exposed in the semiconductor die package. As will be explained in further detail below, at least two (e.g., 2, 3, or 4) folded or formed stand-off structures can enable compression-stress-free internal solder joints and coplanar external exposed pads.

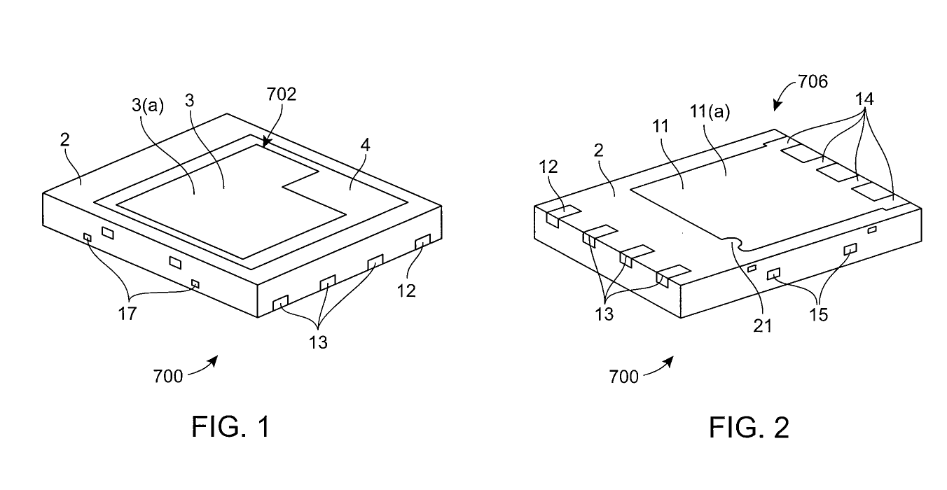

FIG. 1 shows a top perspective view of a semiconductor die package 700 comprising a first molding material 2 surrounding lateral edge and bottom portions of a premolded clip structure 702. In this example, both the top and bottom surfaces of the first molding material 2 and the semiconductor die package 700 may be substantially flat.

The premolded clip structure 702 comprises a source clip 3 comprising an exposed top source pad surface 3(a) and a second molding material 4 which covers at least lateral edge surfaces of the source clip 3. As shown in FIG. 1, the exposed top source pad surface 3(a) is substantially coplanar with the top surface of the second molding material 4 and the first molding material 2. The clip structure 4 may exist as a preformed structure, before the first molding material 2 is formed around the clip structure. Examples of premolded clip structures are described in U.S. patent application Ser. No. 11/626,503, filed on Jan. 24, 2007, which is herein incorporated by reference in its entirety for all purposes, and is assigned to the same assignee as the present application.

The semiconductor die package 700 may comprise at least one gate lead 12 and at least one source lead 13. In this example, there are three source leads 13. The at least one gate lead 12 and the at least one source lead 13 may be part of a leadframe structure 706 (see FIG. 2 and later figures). In this example, terminal surfaces of the gate and source leads 12, 13 are substantially coplanar with the side surfaces of the first molding material 2. Bottom leadframe tie bars 17 are also present in the semiconductor die package 700.

FIG. 2 shows a bottom view of the semiconductor die package shown in FIG. 1. FIG. 2 additionally shows a drain pad 11 (or more generally a central portion), which includes an exterior drain pad surface 11(a) having a pin indicating structure 21 (e.g., a pin 1 indicator) and a plurality of drain leads 14 integral with and extending laterally from the drain pad 11. The drain pad surface 11(a) is substantially coplanar with the bottom surface of the first molding material 2. FIG. 2 also shows terminal surfaces of stand-off structures 15.

In FIGS. 1 and 2, the semiconductor die package 700 may house stacked components that can have flash-free, exposed top and bottom pads. The co-planarity of each component in the stack can be controlled by folded or formed stand-off structures (e.g., 15 in FIG. 2) inside the semiconductor die package 700. The folded or formed stand-off structures can be incorporated into block molded QFN (quad flat no-lead), semi-block or individually molded packages of various sizes. Also, the package 700 shown in FIG. 1 does not have leads that extend past the lateral surfaces of the first molding material 2, and can therefore be characterized as a “no lead” type of package. Other semiconductor die packages according to embodiments of the invention may include leads that extend past the lateral surfaces of the molding material.

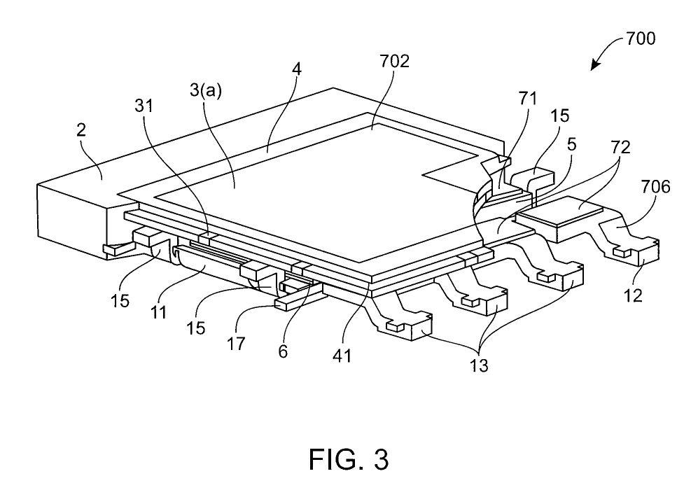

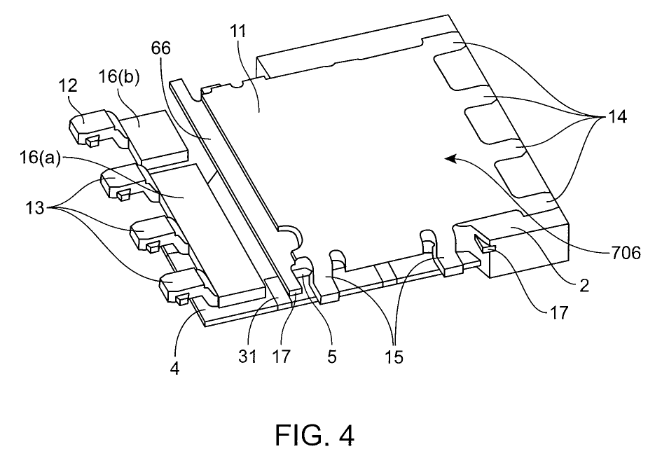

FIGS. 3 and 4 respectively show cut-away perspective top and bottom views of a semiconductor die package.

FIG. 3 shows a stack of components that may reside inside of the semiconductor die package 700. The stack includes a drain pad 11 (i.e., an example of a central portion), a die attach solder 6, a semiconductor die 5, a clip attach solder 71, 72 (or other conductive adhesive such as a conductive epoxy), and a premolded clip structure 702. Terminal ends of tie bars 31 for the source clip 15 may also be present in the premolded clip structure 702. Folded or formed stand-off structures 15 can be integral with and can extend from lateral portions of the drain pad 11. The stand-off structures may have portions, which may support and maintain the planarity of the premolded clip structure 702. A step 41 or other mold locking structure is formed around the peripheral region of the premolded clip structure 702 in the second molding material 4.

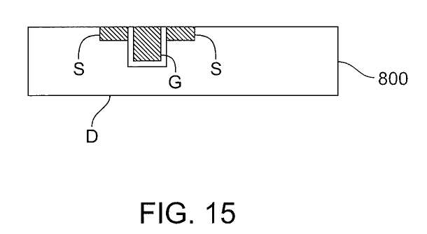

The semiconductor dies used in the semiconductor packages according to preferred embodiments of the invention include vertical power transistors. Vertical power transistors include VDMOS transistors. A VDMOS transistor is a MOSFET that has two or more semiconductor regions formed by diffusion. It has a source region, a drain region, and a gate. The device is vertical in that the source region and the drain region are at opposite surfaces of the semiconductor die. The gate may be a trenched gate structure or a planar gate structure, and is formed at the same surface as the source region. Trenched gate structures are preferred, since trenched gate structures are narrower and occupy less space than planar gate structures. During operation, the current flow from the source region to the drain region in a VDMOS device is substantially perpendicular to the die surfaces. An example of a semiconductor die 800 comprising a vertical MOSFET with a trenched gate is shown in FIG. 15. Other devices that may be present in a semiconductor die may include diodes, BJT (bipolar junction transistors) and other types of electrical devices.

FIG. 4 shows a bottom perspective view of the semiconductor die package 700 shown in FIG. 3 with part of the first molding material 12 being removed. As shown in FIG. 4, the leadframe structure 706 may comprise an exposed drain pad 11 including a bottom half-etched region 66 (or more generally a partially-etched region), a source pad 16(a), and a gate pad 16(b). The source pad 16(a) is integral with and coupled to source leads 13 and the gate pad 16(b) is integral with and coupled to a gate lead 12. The drain pad 11 may have a number of drain leads 14 extending from it. The source and gate terminals 12, 13, as well as the source pad 16(a) and the gate pad 16(b) are electrically isolated from each other. Bottom leadframe tie bars 17 are also shown in FIG. 4.

Referring to FIG. 4, the folded or formed stand-off structures 15 are positioned in such a way that they will come into contact with only the second molding material 4 of the premolded clip structure 702. The contact points between the stand-off structures 15 and the premolded clip structure 702 need not comprise solder. The package 700 may be designed so that there is no electrical connection between stand-off structures 15 and premolded clip structure 702.

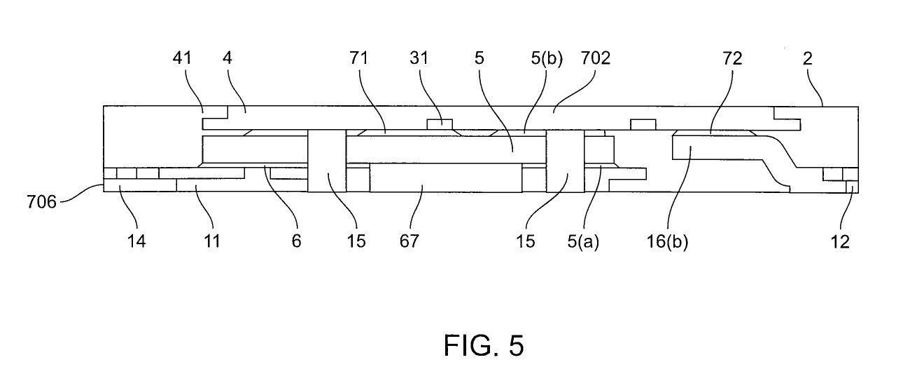

FIG. 5 shows a side view of the semiconductor die package 700. In FIG. 5, only the outline of the previously described first molding material 2 is shown, so that the internal components of the semiconductor die package 700 are visible. As shown in FIG. 5, edge groove structures 67 can be integrally formed with and coupled to a die attach pad 11 (which is an example of a central portion) of the leadframe structure 706. A semiconductor die 5 including a first surface 5(a) and a second surface 5(b) opposite the first surface may be mounted on the die attach pad 11 using a die attach material 6 such as solder or a conductive adhesive. The premolded clip structure 702 may be attached to the second surface 5(b) of the semiconductor die 5, thereby providing source and gate connections to source and gate regions in the semiconductor die 5, and also to the source and gate leads 12, 13.

The stand-off structures 15 can be positioned relative to the premolded clip 702 so that the stand-off structures 15 act as mechanical pillars that provide balance and consistent positioning for the premolded clip structure 702 that is on top of the stand-off structures 15. In embodiments of the invention, the stand-off structures 15 may resemble four legs of a four-legged table. As shown in FIG. 5, the stand-off structures 15 can be an integral part of the bottom leadframe die attach pad 11. Gate and source contact pads 16(a), 16(b) in the leadframe structure 706 may be top-set so that they match up with the height of the stand-off structures 15, and so that the premolded clip structure 702 lies on the stand-off structures 15 as well as the gate and source contact pads 16(a), 16(b). However, in some embodiments, the gate and the source contact pads 16(a), 16(b) may be set slightly lower than the stand-off structure height (e.g., to add a 0.04 mm to accommodate a solder bond line thickness for die attach material 72).

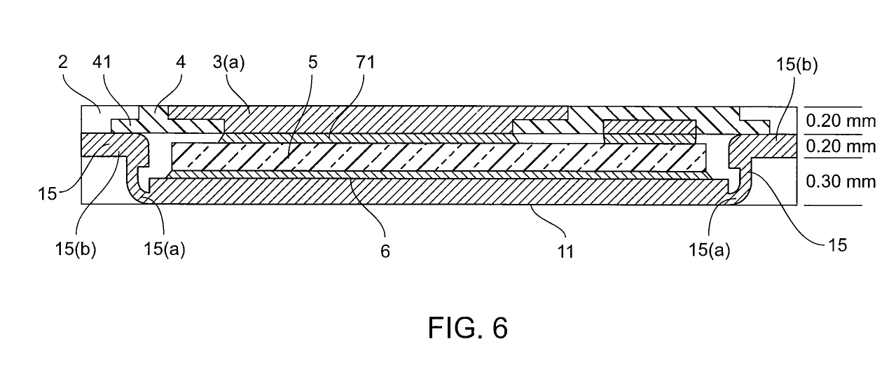

FIG. 6 shows a different cross-sectional view than the side, cross-sectional view of the semiconductor die package in FIG. 5. Referring to FIG. 6, the folded or formed stand-off structures 15 are positioned at opposing sides of the die attach pad 11 to ensure balanced support to the premolded clip structure 702. Whether there is variation in the bond line thickness of die attach solder 6 and clip attach solder 71, or tilting of the semiconductor die 5, the stack of components shown in FIG. 6 would still be planar or horizontal within the semiconductor die package 700.

The stack height can be predetermined by the folded or formed heights provided by the stand-off structures 15. The total stack height in this design can be dictated by the stand-off structure 15 height and the premolded clip 702 thickness. It is apparent that this results in a semiconductor die package 700 with more planar top and bottom surfaces.

The stand-off structures 15, the premolded clip 702, and other components in the semiconductor die package 700 may have any suitable heights. For example, in a specific embodiment, the stand-off structures 15 have heights of about 0.5 mm and the premolded clip structure 702 may have a thickness of about 0.2 mm. The height of the semiconductor die package 700 can be about 0.7 mm in this specific example. The sum of bottom leadframe thickness (0.2 mm), die height (0.2 mm), and top and bottom solder bondline thickness (0.05 mm each) can be within the stand-off structure 15 height. Other suitable thicknesses may be more or less than these values.

As shown in FIG. 6, each stand-off structure 15 may include a vertical portion 15(a) and a support portion 15(b) substantially perpendicular to the vertical portion 15(a). The vertical portion 15(a) may include a curved region in this example. This can provide the stand-off structure 15 with some flexibility if force is applied downward on the support portion 15(a). However, the vertical portion 15(a) need not have a curved portion in other embodiments. For example, the vertical portion 15(a) could extend straight up from the central portion 11 without a curved portion in other embodiments. As shown in FIG. 6, the premolded clip structure 702 rests on the support portions 15(b) of the stand-off structures 15.

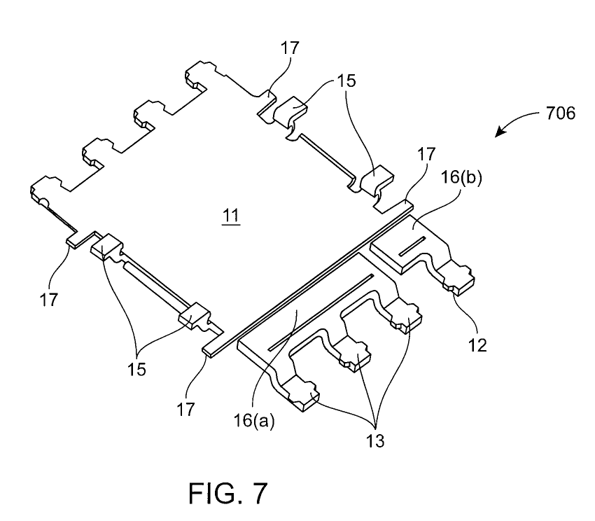

FIG. 7 shows a top, perspective view of a leadframe structure 706. The positions of the stand-off structures 15 are balanced and congruent at both edges of the die attach pad 11. The stand-off structures 15 have support portions (as described above) to ensure good coplanarity control during leadframe fabrication. Each support portion may also serve as stand-off tie bar to enable multiple units within an array of the leadframe structures.

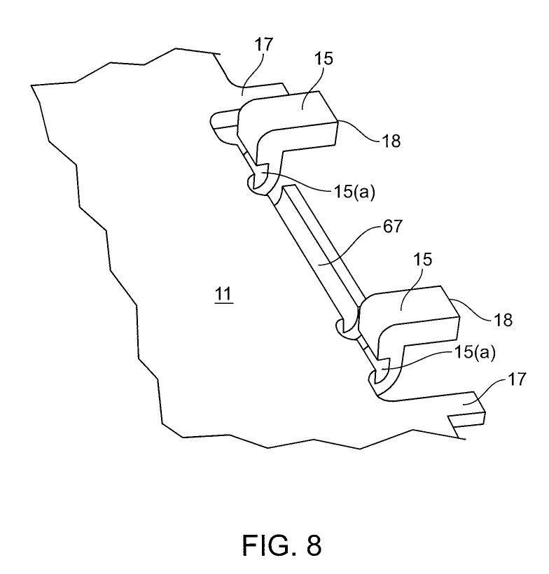

Referring to FIG. 8, the stand-off structures 15 are shown here with vertical portions 15(a) with internal corner reliefs. The internal corner relief in the vertical portion 15(a) will add flexibility of the stand-off structure during molding. When compressive stress is applied during molding (mold clamp pre-load), the point of deformation is targeted to be at the inner corner of the stand-off structure 15, where the resisting area is at about half of the leadframe structure thickness. As shown in FIG. 8, the stand-off structures 15 are integral to the die attach pad 11. The die attach pad 11 has a groove 67 at its edges to catch excess die attach material during processing. It is also bent up during the formation of stand-off structure 15.

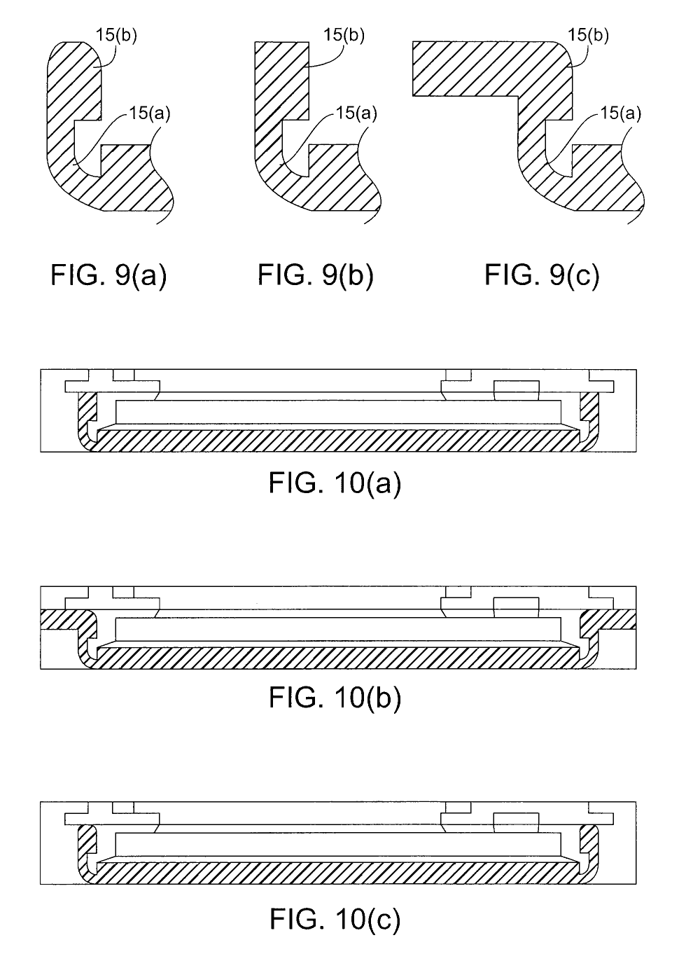

Referring to FIGS. 9(a)-9(c) and 10(a)-10(c), there are three options of folded or formed stand-off structures. Other options are also possible. FIG. 9(a) shows a stand off structure with a vertical portion 15(a) and a rounded support portion 15(b). FIG. 9(b) shows a stand off structure with a vertical portion 15(a) and a support portion 15(b) with an upper flat surface. FIG. 9(c) shows a stand-off structure with a vertical portion 15(a) and a support portion 15(b) in the form of a topset pad. FIGS. 10(a)-10(c) respectively show packages with stand off structures including the stand-off structures that are respectively shown in FIGS. 9(a)-9(c).

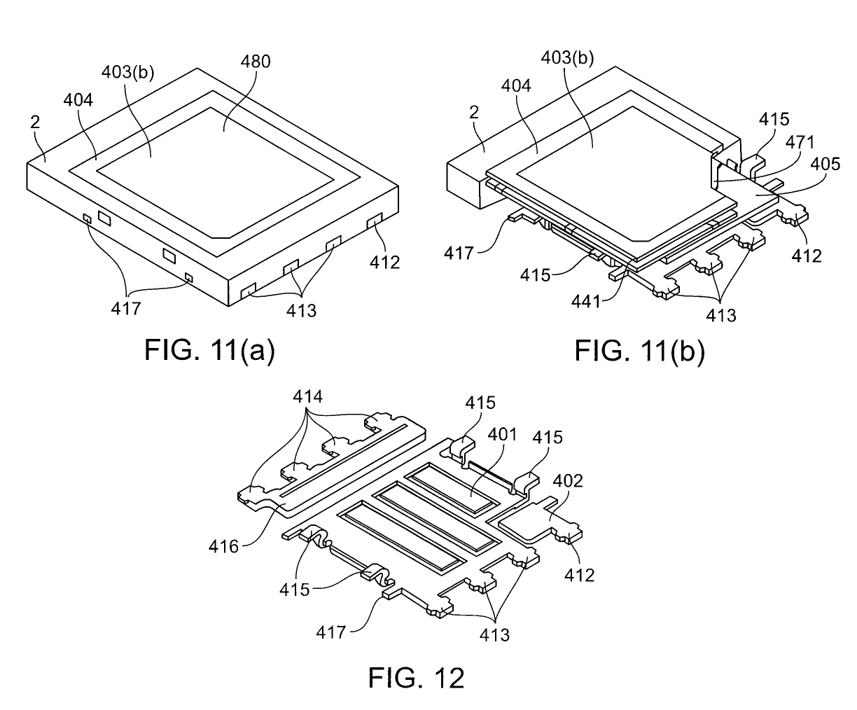

FIG. 11(a) shows a semiconductor die package with an exposed top drain. FIG. 11(b) shows the package in FIG. 11(a) with a portion of the molding material cut away, and FIG. 12 shows a bottom leadframe structure.

FIGS. 11(a)-11(b) show folded stand-off structures in a semiconductor die package that has an exposed top drain, as opposed to exposed top source pad. Referring to FIGS. 11(a)-11(b), a first molding material 2 surrounds lateral edges of a premolded drain clip structure 480 comprising a drain pad 403(b) and a first molding material 404. A mold locking structure 441 may be formed in the premolded drain clip structure 480. Terminal ends of tie bars 417, and portions of a gate terminal 412 and source terminals 413 are exposed at lateral regions of the first molding material 2. The drain clip structure 480 can be attached to a semiconductor die 405 using clip attach solder 471. As shown in FIG. 11(b), stand-off structures 415 are present in a leadframe structure.

FIG. 12 shows a leadframe structure. As shown in FIG. 12, the leadframe structure includes stand-off structures 415. It includes drain terminals 414 extending from a drain pad 416. It also includes a source pad 401 (i.e., an example of a central portion) with source terminals 413 extending from it, and a gate pad 402 with a gate terminal 412 extending from it.

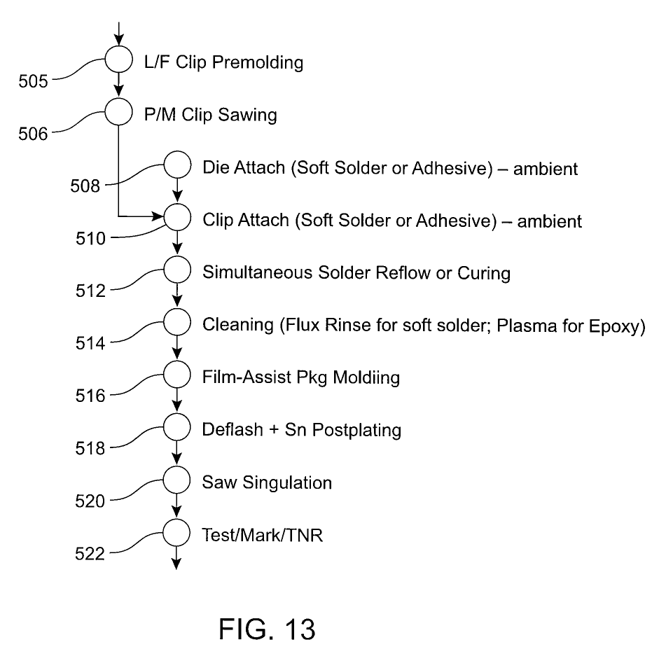

FIG. 13 shows an exemplary process flow for a method according to an embodiment of the invention.

FIG. 13 illustrate steps (505 and 506) that are used in the formation of a premolded clip structure. In step 505, a clip is first premolded. The clip may be first obtained by a process such as stamping or etching. The clip may be in an array and the array of clips may be molded using a tape assisted molding process or a molding process using a molding tool using molding dies. Such molding processes are well known in the art. Then, after molding, the premolded clip structures are then separated from other premolded clip structures in an array of premolded clip structures.

Before or after the premolded clip structure is formed, solder can be deposited on a semiconductor die, and the semiconductor die can be attached to the leadframe structure (step 508). Solder can be deposited using any suitable process including solder bumping, etc. Also, any suitable type of solder (or other type of conductive material such as a conductive epoxy) may be used (e.g., PbSn or lead free solder).

After the leadframe structure is attached to the semiconductor die, the premolded clip structure may be attached to the semiconductor die and the leadframe structure (step 510). Solder or some other conductive adhesive may be used to attach the semiconductor die to the premolded clip structure.

Then, a solder reflow or curing step may take place (step 512) followed by a cleaning step (step 514). A flux rinse may be performed for soft solder and a plasma process may be used for epoxy.

A film-assisted package molding process can then be performed (step 516) to form the previously described first molding material around the premolded clip structure, semiconductor die, and the leadframe structure.

A deflash process and/or a postplating process (step 518) can then be performed. In a deflash process, excess molding material can be removed. In a postplating process, leads can be plated with a solderable material, if desired.

After deflash and postplating, a saw singulation process can be performed (step 520) to separate packages within an array from each other.

Then, a test, mark, and TNR process may be performed (step 522).

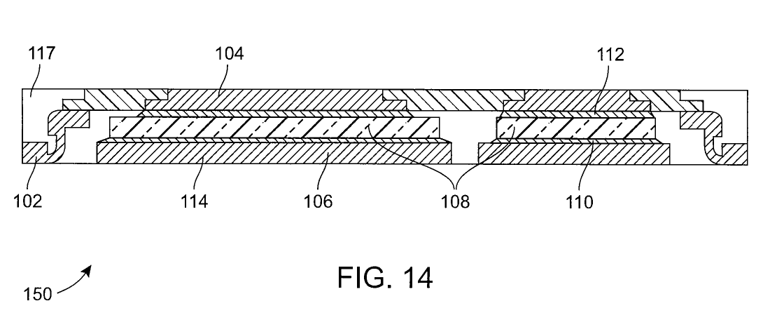

FIG. 14 shows another package according to another embodiment of the invention. This package includes a leadframe structure 114 with stand-off structures 102 and a die attach pad 106. In this example, the stand-off structures 102 are not integral with the die attach pad 106 as in other embodiments, but are coupled to it via a molding material 117. A die attach material 110 is used to attach a semiconductor die 108 to the leadframe structure 114. In this package 150, there are two semiconductor dies 108.

An exposed top conductive structure 104 can rest on the semiconductor dies 106 and the stand-off structures 102. It may comprise any suitable composite material. It may include a premolded clip structure (as described above), a BT laminate, or similar material with defined conductive areas and contact and top exposed pads. A clip attach material 112 may be used to couple the exposed tops structure 104 to the semiconductor dies 108.

FIG. 15 shows a schematic cross-section of a semiconductor die with a vertical transistor, and FIG. 15 is described above.

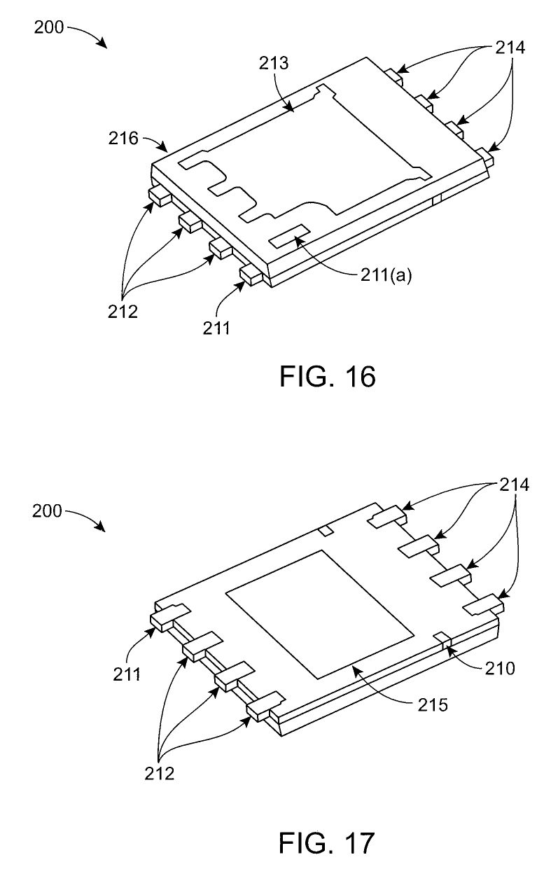

FIG. 16 shows a top perspective view of another semiconductor die package 200 according to an embodiment of the invention. In this embodiment, the package 200 has a surface of a semiconductor die that is exposed through a molding material.

FIG. 16 shows a semiconductor die package 200 comprising an exposed gate pad 211(a) and an integral gate lead 211, and an exposed source pad 213 with integral source leads 212. Dummy leads 214 are at one side of the semiconductor die package 200 while source leads 212 and a gate lead 211 are at the other side of the package 200. A molding material 216 covers at least portions of the previously described components. The molding material 216 also has an exterior surface that is substantially coplanar with the surfaces of the source pad 213, and the exposed gate pad 211(a).

FIG. 17 shows a top perspective view of the semiconductor die package 200 shown in FIG. 16. FIG. 17 additionally shows a stand-off structure 210 that may also be a source pad tie bar. An exposed silicon drain region 215 is substantially coplanar with the bottom surface of the molding material 216.

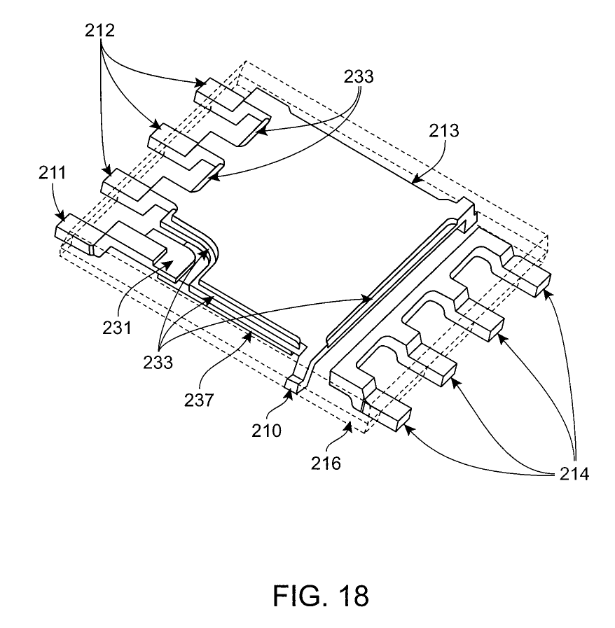

FIG. 18 shows a top perspective view of the semiconductor die package shown in FIG. 16, with only the outline of the molding material 216 shown. FIG. 18 shows a leadframe structure comprising an exposed source pad 213 having source leads 212 extending from it, and a half-etched (or partially) region 233. It also shows a half-etched gate pad 231 and a corresponding gate lead 211. The half-etched gate pad 231 can be used for mold locking to a molding material. A semiconductor die 237 is coupled to the leadframe structure using a die attach material such as solder.

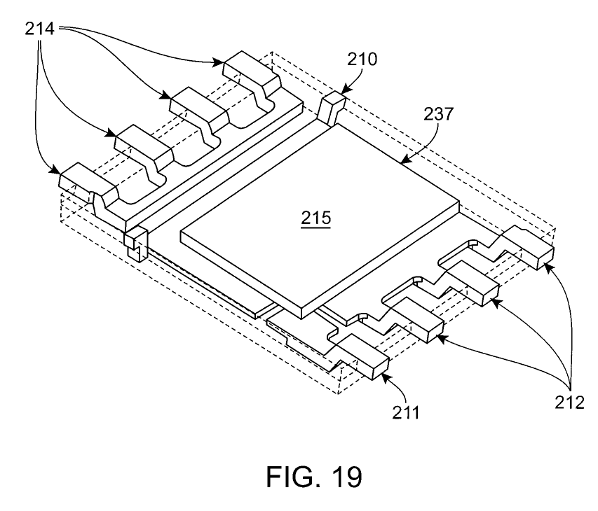

FIG. 19 shows a bottom perspective view of the semiconductor die package shown in FIG. 18, with only the outline of the molding material 216 shown. As shown, the drain surface 215 is facing upward in FIG. 19, and can correspond to a second surface of the semiconductor die 237. The first surface of the semiconductor die 237 can face the leadframe structure.

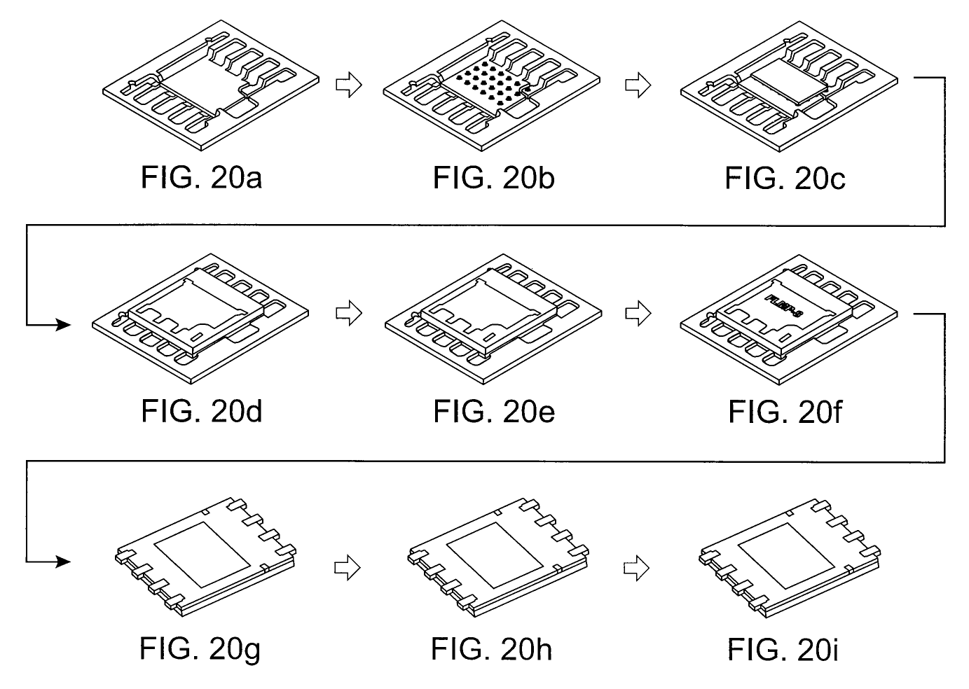

FIGS. 20(a)-20(b) show a process flow used to make the die package shown in FIGS. 16-17.

FIG. 20(a) shows a leadframe. FIG. 20(b) shows a structure that is formed after a solder paste dispense process. FIG. 20(c) shows a structure after a flip chip attach and reflow process. FIG. 20(d) shows a structure after a film assisted molding process. FIG. 20(e) shows a structure formed after a water jet deflash process. FIG. 20 shows a structure formed after a marking process. FIG. 20(g) shows a structure formed after a singulation process. FIG. 20(h) shows a structure that is formed after a unit test, and FIG. 20(i) shows a structure formed after a pack and ship process.

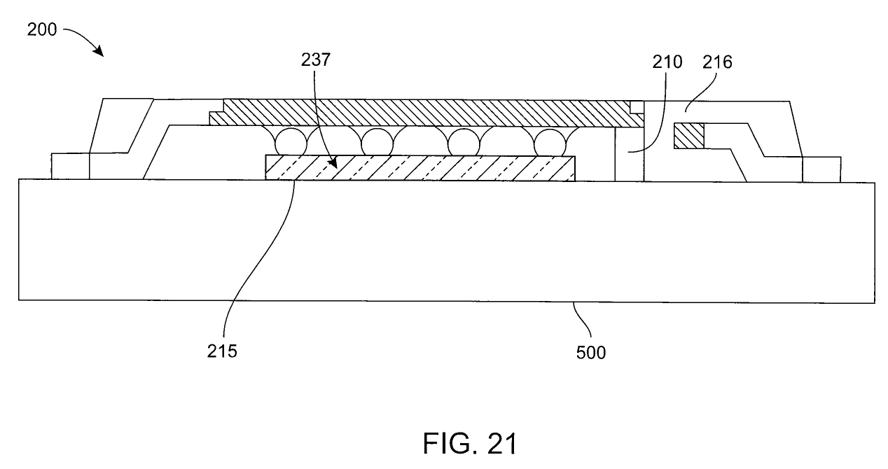

FIG. 21 shows an assembly according to an embodiment of the invention. FIG. 21 shows a semiconductor die package 200 mounted on a circuit substrate 500. The bottom of the package 200 can be substantially flush with the top surface of the circuit substrate 500 so that the bottom drain surface 215 of the die 237 is on contact with an electrical pad (not shown) in the circuit substrate 500. The stand-off structure 210 helps to maintain planarity with respect to the upper surface of the circuit substrate 500. The bottom surface of the molding material 216 may also be substantially coplanar with the bottom surface of the semiconductor die 237.

The following features are noted in embodiments of the invention:
The folded or formed stand-off structures can act as balanced pillars for a top exposed pad structure of a semiconductor die package. The stand-off structures may be mechanical structures, without any electrical connection to the top exposed pad structure of the semiconductor die package.
The stand-off structures may also provide for a pre-determined stack height without being affected by the variation in the bond line thicknesses of the top and bottom die connections.
The stand-off structures can control the planarity of the stack of components in the package, thus enabling flash-free top and bottom exposed package molding.
The stand-off structures can have internal corner relief structures at their bases to add flexibility during molding. Their locations in the package can be the primary stress absorbing points to divert applied compressive stress during molding from the stack assembly to only the peripheral stand-off contact areas.
The stand-off structures enable the manufacturing process to provide for simultaneous soldering reflow or curing of the top and bottom die connections with minimal movement of the stack assembly, thus ensuring a coplanar stack height after the reflow or curing process.
The stand-off structures can have either rounded tips, flat tips, or top pads.
The stand-off structures can either be integrated into bottom leadframe functional pad(s) or isolated from any functional pad in a package.
The stand-off structure tips can ensure coplanarity.
A modified premolded clip can have an indented structure for steadfast stack assembly and final package mold locking.
The top exposed clip structure and stand-off contact points can be non-soldered, or electrically isolated from each other.
Non-electrical contact stand-off structures and the clip designs according to embodiments of the invention enable various terminal configurations using the same manufacturing process flow.

Embodiments of the invention provide a number of other advantages. First, the stand-off structures will prevent tilting and rotation of the components in the stack due to the flow of solder or adhesive material at the bottom and top side connections of the die. Second, the stand-off structures serve as non-soldered supports. Defined points of contact with topside connections serve as concentrated stress points that will divert the compressive stress from the stack assembly to the stand-off structure. It acts primarily as shock absorber, keeping the die and solder joints from cracking under compression. Third, uniform heights at all corners of the stack assembly ensure control of mold flashes during molding. Fourth, the internal corner relief at the base of the folded structure enables effective top mold clamping preload, and thus, controls mold resin flash at the topside exposed pad of the molded package.

Other advantages include: less stressful solder joints, better reliability; controlled mold flashing at the top and bottom of the package; versatile design, applicable to other packages with multiple layers; application to multi-chip modules; lower tooling capitalization costs; and use of universal mold tools.

As used herein “top” and “bottom” surfaces are used in the context of relativity with respect to a circuit board upon which the semiconductor die packages according to embodiments of the invention are mounted. Such positional terms may or may not refer to absolute positions of such packages.

The semiconductor die packages described above can be used in electrical assemblies including circuit boards with the packages mounted thereon. They may also be used in systems such as phones, computers, etc.

Any recitation of “a”, “an”, and “the” is intended to mean one or more unless specifically indicated to the contrary.

The terms and expressions which have been employed herein are used as terms of description and not of limitation, and there is no intention in the use of such terms and expressions of excluding equivalents of the features shown and described, it being recognized that various modifications are possible within the scope of the invention claimed.

Moreover, one or more features of one or more embodiments of the invention may be combined with one or more features of other embodiments of the invention without departing from the scope of the invention.

What is claimed is:

1. A leadframe structure comprising:
a central portion suitable for supporting a semiconductor die comprising a first surface and a second surface opposite the first surface; and
a plurality of stand-off structures coupled to or spaced from the central portion.

2. The leadframe structure of claim 1 wherein the stand-off structures are suitable for supporting a premolded clip structure, wherein the premolded clip structure is capable of being attached to the second surface of the semiconductor die.

3. The leadframe structure of claim 1 wherein the leadframe structure comprises copper.

4. The leadframe structure of claim 1 wherein the plurality of stand-off structures comprises at least four stand-off structures, wherein there is at least one stand-off structure extending from each edge of the central portion.

5. The leadframe structure of claim 1 wherein the central portion is a drain pad.

6. The leadframe structure of claim 5 further comprising a gate lead and a source lead spaced from the central portion.

7. A method comprising:
stamping a metal sheet to form the leadframe structure of claim 1.

8. A semiconductor die package comprising:
a semiconductor die comprising a first surface and a second surface opposite the first surface; and
a leadframe structure comprising a central portion suitable for supporting the semiconductor die, and a plurality of stand-off structures coupled to the central portion of the leadframe structure, wherein the stand-off structures are capable of maintaining planarity with respect to a conductive structure comprising a planar surface.

9. The semiconductor die package of claim 8 wherein the conductive structure is a premolded clip structure, and wherein the stand-off structures are coupled to the central portion by being integral with the central portion.

10. The semiconductor die package of claim 8 wherein the semiconductor die comprises a source region and a gate region at the first surface and a drain region at the second surface, and wherein the conductive structure is a printed circuit substrate.

11. The semiconductor die package of claim 8 further comprising a molding material covering at least a portion of the leadframe structure, wherein the molding material exposes the second surface of the semiconductor die.

12. The semiconductor die package of claim 8 wherein the plurality of stand-off structures comprises at least four stand-off structures, wherein there is at least one stand-off structure extending from each edge of the central portion

13. The semiconductor die package of claim 8 further comprising a conductive adhesive between the conductive structure and the semiconductor die.

14. The semiconductor die package of claim 13 wherein the conductive adhesive comprises solder.

15. A method for forming a semiconductor die package, the method comprising:
obtaining a semiconductor die comprising a first surface and a second surface opposite the first surface;
obtaining a leadframe structure comprising a central portion surface suitable for supporting the semiconductor die, and a plurality of stand-off structures; and
attaching the leadframe structure to the semiconductor die.

16. The method of claim 15 wherein the semiconductor die comprises a source region and a gate region at the first surface and a drain region at the second surface.

17. The method of claim 15, further comprising, attaching a conductive structure to the stand-off structures and to the semiconductor die.

18. The method of claim 17 wherein attaching the conductive structure to the semiconductor die comprises using a conductive adhesive to attach the conductive structure and the semiconductor die.

19. The method of claim 15 wherein the stand-off structures are integral with the central portion.

20. The method of claim 15 further comprising molding a molding material around at least a portion of the semiconductor die and at least a portion of the leadframe structure.
